(19) United States
(12) Patent Application Publication
(10) Pub. No.: US 2025/0357158 A1
(43) Pub. Date: Nov. 20, 2025

(54) SEPARATION DEVICE

(71) Applicant: SILICONWARE PRECISION INDUSTRIES CO., LTD., Taichung City (TW)

(72) Inventors: Kuo-Ching TSAI, Taichung City (TW); Yu-Chih CHENG, Taichung City (TW); Jen-Chao LIOU, Taichung City (TW); Yi-Lun YANG, Taichung City (TW)

(73) Assignee: SILICONWARE PRECISION INDUSTRIES CO., LTD., Taichung City (TW)

(21) Appl. No.: 18/824,303

(22) Filed: Sep. 4, 2024

(30) Foreign Application Priority Data
May 14, 2024 (TW) 113117751

(51) Int. Cl. H01L 21/67

(52) U.S. Cl. CPC H01L 21/67132

(57) ABSTRACT

A separation device is provided and includes: a pin cover having an action platform and an accommodating space for an object to be separated to be placed on the action platform, where the action platform is defined with an active region and an idle region, the active region is provided with a plurality of first apertures, and the plurality of first apertures penetrate through the action platform and communicate with the accommodating space; an ejector pin plate disposed in the accommodating space; a plurality of ejector pins disposed on the ejector pin plate and corresponding to positions of the plurality of first apertures; and a plurality of bumps disposed in the idle region of the action platform, so that the bumps can provide sufficient support for the object to be separated without hindering the separation operation of the ejector pins.

### BACKGROUND

### 1. Technical Field

The present disclosure relates to a separation device, and more particularly, to a separation device for separating a semiconductor device and an adhesive film.

### 2. Description of Related Art

With the vigorous development of technologies such as artificial intelligence (AI), cloud, big data analysis and mobile computing, modern society has increasingly higher demands for computing power. Therefore, in addition to continuing to develop advanced processes, the semiconductor industry is also looking for ways to keep chips small while maintaining high performance. The concept of “heterogeneous integration” has therefore become a prominent concept in modern times, and chips have also shifted from the original single layer to multi-layer stacked advanced packaging.

Chip-on-wafer-on-substrate (CoWoS) is an integrated production technology, in which the chip is connected to the wafer via the chip-on-wafer (CoW) packaging process, and then the CoW chip is connected to the substrate, thereby being integrated into a CoW-on-substrate.

In the CoWoS process, when a plurality of chips are integrated to form a plurality of chip modules, a separation device having a plurality of ejector pins is required to use the plurality of ejector pins to eject each of the chip modules from the temporarily fixed adhesive film. However, in order to avoid damage to some fragile chips caused by the stress of the ejector pin, the distribution of the plurality of ejector pins must avoid installation regions of the fragile chips, resulting in limited distribution regions of the plurality of ejector pins. Therefore, in actual operation, the plurality of ejector pins of the separation device can only push against some limited regions of the chip module. This may cause some regions of the chip module to detach from the adhesive film and some regions of the chip module to remain adhered to the adhesive film, thereby causing the chip module to deflect and even causing damage to the chip module.

Therefore, how to overcome the above-mentioned drawbacks of the prior art has become an urgent issue to be solved at present.

### SUMMARY

In view of the various deficiencies of the prior art, the present disclosure provides a separation device, which comprises: a pin cover having an action platform and an accommodating space for an object to be separated to be placed on the action platform, wherein the action platform is defined with an active region and an idle region, the active region is provided with a plurality of first apertures, and the plurality of first apertures penetrate through the action platform and communicate with the accommodating space; an ejector pin plate disposed in the accommodating space; a plurality of ejector pins disposed on the ejector pin plate and corresponding to positions of the plurality of first apertures; and a plurality of bumps disposed in the idle region of the action platform of the pin cover.

In the aforementioned separation device, the idle region is provided with a plurality of second apertures, and the plurality of second apertures penetrate through the action platform and communicate with the accommodating space. Further, the active region is located at a center of the action platform, and the idle region is located around the active region.

In the aforementioned separation device, the ejector pin plate is defined with a first connection region and a second connection region, wherein the first connection region and the second connection region are parallel to the action platform, and the plurality of ejector pins are disposed in the first connection region of the ejector pin plate. Further, the bumps are cones. The plurality of bumps and the pin cover are integrally formed.

In the aforementioned separation device, the object to be separated includes an adhesive film and a chip module disposed on the adhesive film, and the separation device is used to separate the adhesive film and the chip module. The chip module is defined with a first region and a second region, the first region is located at a center of the chip module, the second region is located around the first region, the first region is provided with a first chip, and the second region is provided with a second chip. The first region of the chip module is located corresponding to the active region of the pin cover, and the second region of the chip module is located corresponding to the idle region of the pin cover.

In the aforementioned separation device, a distribution region of the active region of the pin cover accounts for 60% of a distribution area of the action platform of the pin cover.

In the aforementioned separation device, the object to be separated is fixed on the pin cover by vacuum suction. The ejector pin plate moves toward the pin cover, so that the plurality of ejector pins pass through the plurality of first apertures and press against the object to be separated. A contact area between the bumps and the object to be separated is smaller than a contact area between the ejector pins and the object to be separated.

In the aforementioned separation device, the present disclosure further comprises ejector blocks disposed on the ejector pin plate. The idle region of the pin cover is provided with openings connected to the accommodating space, and the ejector blocks correspond to positions of the openings. The ejector blocks are further provided with the plurality of bumps.

As can be seen from the above, in the separation device of the present disclosure, by disposing a plurality of bumps such as cones in the region where a plurality of ejector pins are not disposed on the pin cover, or even adding ejector blocks and disposing a plurality of bumps on the ejector blocks, the contact area between the bumps and the object to be separated is smaller than the contact area between the ejector pins and the object to be separated. Accordingly, the bumps can provide sufficient support for the object to be separated without hindering the separation operation of the ejector pins, such that the situation that the plurality of ejector pins of the conventional separation device can only push against a portion of a limited region of the object to be separated can be avoided (since the plurality of ejector pins of the conventional separation device can only push against a portion of a limited region of the object to be separated, some regions of the object to be separated may be separated from the adhesive film and some regions may still be adhered to the adhesive film, causing problems such as deflection or even damage of the object to be separated).

### BRIEF DESCRIPTION OF THE DRAWINGS

FIG. 1A and FIG. 1B are schematic cross-sectional views of a separation device and an operation thereof according to the present disclosure.

FIG. 1C is a partially enlarged schematic view of a bump and an ejector pin of

the separation device according to the present disclosure.

FIG. 2A and FIG. 2B are schematic cross-sectional views of the separation device and the operation thereof according to another embodiment of the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

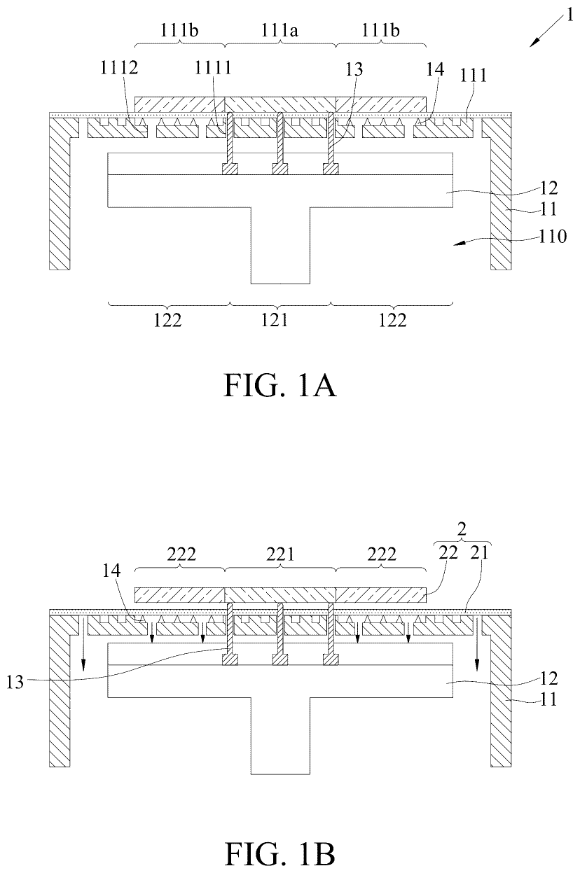

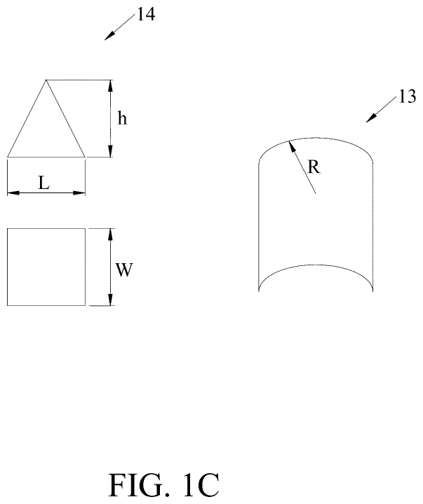

Please refer to FIG. 1A and FIG. 1B, which are schematic cross-sectional views of a separation device 1 and an operation thereof of the present disclosure.

As shown in FIG. 1A and FIG. 1B, the separation device 1 includes a pin cover 11, an ejector pin plate 12, a plurality of ejector pins 13 and a plurality of bumps 14.

The pin cover 11 is provided with an action platform 111 and an accommodating space 110 for an object 2 to be separated to be placed on the action platform 111. Furthermore, the action platform 111 is defined with an active region 111a and an idle region 111b, wherein the active region 111a is provided with a plurality of first apertures 1111, and the idle region 111b is provided with a plurality of second apertures 1112, and wherein the plurality of first apertures 1111 and the plurality of second apertures 1112 penetrate through the action platform 111 and communicate with the accommodating space 110. In one embodiment, the active region 111a is located at the center position of the action platform 111, and the idle region 111b is located around the active region 111a.

The ejector pin plate 12 is located in the accommodating space 110 and has a first connection region 121 and a second connection region 122, wherein the first connection region 121 and the second connection region 122 are parallel to the action platform 111.

The plurality of ejector pins 13 are disposed on the first connection region 121 of the ejector pin plate 12 and correspond to the positions of the plurality of first apertures 1111 in the active region 111a.

The plurality of bumps 14 are disposed on the idle region 111b of the action platform 111 of the pin cover 11, wherein the shape of each of the bumps 14 is, for example, a cone. In one embodiment, the plurality of bumps are, for example, pyramid-shaped (tetragonal pyramid) and are arranged in an array in the idle region 111b. In addition, the plurality of bumps 14 can be integrally formed with the pin cover 11.

During operation, the object 2 to be separated is placed on the action platform 111 of the pin cover 11. In one embodiment, the object 2 to be separated includes an adhesive film 21 and a chip module 22 disposed on the adhesive film 21. The separation device 1 is mainly used to separate the adhesive film 21 and the chip module 22.

In one embodiment, the chip module 22 is defined with a first region 221 and a second region 222, wherein the first region 221 is located at the center position of the chip module 22, and the second region 222 is located around the first region 221, and wherein the first region 221 is provided with a first chip (such as a graphics processing unit [GPU]), and the second region 222 is provided with a second chip (such as a high bandwidth memory [HBM]).

Furthermore, an image sensor can be used to assist in positioning, and the object 2 to be separated (i.e., the adhesive film 21 and the chip module 22) is placed at a predetermined position of the pin cover 11, so that the first region 221 of the chip module 22 is located corresponding to the active region 111a of the pin cover 11, and the second region 222 of the chip module 22 is located corresponding to the idle region 111b of the pin cover 11. In one embodiment, the distribution region of the active region 111a (that is, the first region 221 of the chip module 22) of the pin cover 11 accounts for approximately 60% of the distribution area of the action platform 111 (the active region 111a+the idle region 111b, that is, the first region 221+the second region 222 of the entire chip module 22) of the pin cover 11.

Then, the adhesive film 21 and the chip module 22 can be fixed on the pin cover 11 by vacuum suction (as shown by arrows in FIG. 1B), wherein a vacuum suction device (not shown) is used to generate a downward suction force via the plurality of second apertures 1112, so that the adhesive film 21 at the first region 221 of the chip module 22 is lightly in contact with the plurality of ejector pins 13 exposing from the plurality of first apertures 1111, while the adhesive film 21 at the second region 222 of the chip module 22 is lightly in contact with the plurality of bumps 14.

The ejector pin plate 12 is then moved toward the pin cover 11, so that the plurality of ejector pins 13 pass through the plurality of first apertures 1111 and press against the adhesive film 21 and the chip module 22. Since the adhesive film 21 is still being sucked by the downward suction force of the second apertures 1112, the chip module 22 will be separated from the adhesive film 21 by being pushed against by the plurality of ejector pins 13.

Therefore, in the separation device 1 of the present disclosure, the plurality of ejector pins 13 are pressed against the first region 221 of the chip module 22, and the plurality of bumps 14 are used to contact the second region 222 of the chip module 22, wherein, as shown in FIG. 1C, since each of the bumps 14 is configured as a cone (the length: width: height [L:W:h] ratio of the cone is 1:1:1), and the contact area between the cone and the second region 222 of the chip module 22 is smaller than the contact area between the ejector pin 13 (head size R of the ejector pin>0.35 mm) and the first region 221 of the chip module 22, so the second region 222 of the second chip in contact with the bumps 14 is less susceptible to damage.

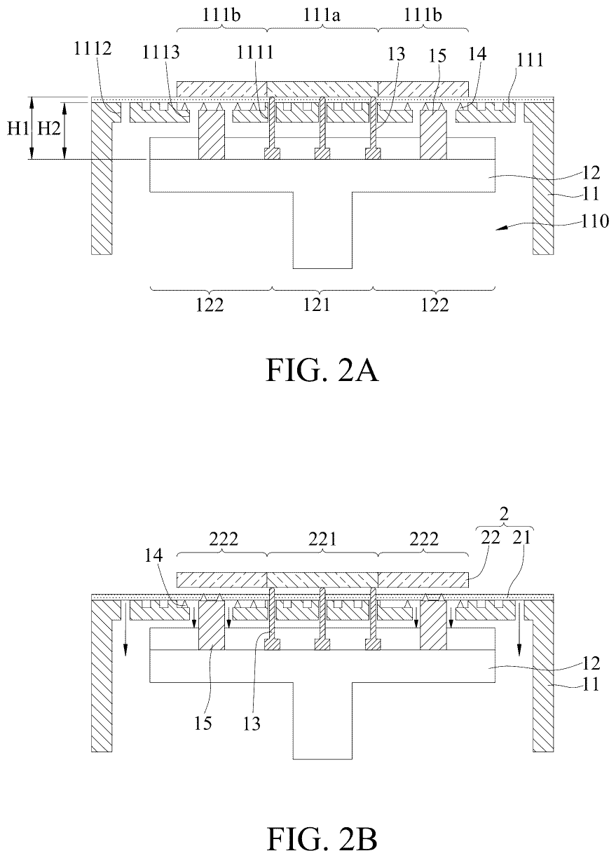

Please refer to FIG. 2A and FIG. 2B, which are schematic cross-sectional views of the separation device 1 and the operation thereof according to another embodiment of the present disclosure.

This embodiment is substantially the same as the previous embodiment. In this embodiment, the action platform 111 of the pin cover 11 is defined with an active region 111a and an idle region 111b located around the active region 111a, wherein the active region 111a is provided with a plurality of first apertures 1111, the idle region 111b is provided with a plurality of second apertures 1112 and at least one opening 1113, and the plurality of first apertures 1111, the plurality of second apertures 1112 and the openings 1113 penetrate through the action platform 111 and communicate with the accommodating space 110.

A plurality of ejector pins 13 are disposed on the first connection region 121 of the ejector pin plate 12, and correspond to the positions of the plurality of first apertures 1111 of the active region 111a, wherein a plurality of bumps 14 are disposed on the idle region 111b of the action platform 111 of the pin cover 11, and at least one ejector block 15 is disposed on the second connection region 122 of the ejector pin plate 12 and corresponds to the position of the at least one opening 1113 of the idle region 111b while a plurality of bumps 14 are disposed on the ejector blocks 15, wherein the plurality of bumps 14 are, for example, cones.

During operation, the object 2 to be separated (including the adhesive film 21 and the chip module 22 disposed on the adhesive film 21) is placed on the action platform 111 of the pin cover 11, and a downward suction force (as shown by the arrows in FIG. 2B) is generated via the plurality of second apertures 1112 and the at least one opening 1113 by vacuum suction, so as to fix the adhesive film 21 and the chip module 22 on the pin cover 11.

The chip module 22 is defined with a first region 221 and a second region 222, wherein the first region 221 is located at the center position of the chip module 22, the second region 222 is located around the first region 221, and wherein the first region 221 is provided with a first chip, and the second region 222 is provided with a second chip. The first region 221 of the chip module 22 is located corresponding to the active region 111a of the pin cover 11, and the second region 222 of the chip module 22 is located corresponding to the idle region 111b of the pin cover 11.

Then the ejector pin plate 12 is moved toward the pin cover 11, so that the plurality of ejector pins 13 pass through the plurality of first apertures 1111. At the same time, the ejector blocks 15 pass through the openings 1113, and then press against the adhesive film 21 and the chip module 22. Since the adhesive film 21 is still being sucked by the downward suction force, the chip module 22 will be separated from the adhesive film 21 by being pushed against by the plurality of ejector pins 13 and the ejector blocks 15.

In one embodiment, the height H1 of each of the ejector pins 13 is greater than the height H2 of each of the ejector blocks 15 and each of the bumps 14, and the ejector pins 13 and the ejector blocks 15 can simultaneously push against the chip module.

In summary, in the separation device of the present disclosure, by disposing a plurality of bumps such as cones in the region where a plurality of ejector pins are not disposed on the pin cover, or even adding ejector blocks and disposing a plurality of bumps on the ejector blocks, the contact area between the bumps and the object to be separated is smaller than the contact area between the ejector pins and the object to be separated. Accordingly, the bumps can provide sufficient support for the object to be separated without hindering the separation operation of the ejector pins, such that the situation that the plurality of ejector pins of the conventional separation device can only push against a portion of a limited region of the object to be separated can be avoided (since the plurality of ejector pins of the conventional separation device can only push against a portion of a limited region of the object to be separated, some regions of the object to be separated may be separated from the adhesive film and some regions may still be adhered to the adhesive film, causing problems such as deflection or even damage of the object to be separated).

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A separation device, comprising:
a pin cover having an action platform and an accommodating space for an object to be separated to be placed on the action platform, wherein the action platform is defined with an active region and an idle region, the active region is provided with a plurality of first apertures, and the plurality of first apertures penetrate through the action platform and communicate with the accommodating space;
an ejector pin plate disposed in the accommodating space;
a plurality of ejector pins disposed on the ejector pin plate and corresponding to positions of the plurality of first apertures; and
a plurality of bumps disposed in the idle region of the action platform of the pin cover.

2. The separation device of claim 1, wherein the idle region is provided with a plurality of second apertures, and the plurality of second apertures penetrate through the action platform and communicate with the accommodating space.

3. The separation device of claim 1, wherein the active region is located at a center of the action platform, and the idle region is located around the active region.

4. The separation device of claim 1, wherein the ejector pin plate is defined with a first connection region and a second connection region, wherein the first connection region and the second connection region are parallel to the action platform, and the plurality of ejector pins are disposed in the first connection region of the ejector pin plate.

5. The separation device of claim 1, wherein the bumps are cones.

6. The separation device of claim 1, wherein the plurality of bumps and the pin cover are integrally formed.

7. The separation device of claim 1, wherein the object to be separated includes an adhesive film and a chip module disposed on the adhesive film, and the separation device is used to separate the adhesive film and the chip module.

8. The separation device of claim 7, wherein the chip module is defined with a first region and a second region, the first region is located at a center of the chip module, the second region is located around the first region, the first region is provided with a first chip, and the second region is provided with a second chip.

9. The separation device of claim 8, wherein the first region of the chip module is located corresponding to the active region of the pin cover, and the second region of the chip module is located corresponding to the idle region of the pin cover.

10. The separation device of claim 1, wherein a distribution region of the active region of the pin cover accounts for 60% of a distribution area of the action platform of the pin cover.

11. The separation device of claim 1, wherein the object to be separated is fixed on the pin cover by vacuum suction.

12. The separation device of claim 1, wherein the ejector pin plate moves toward the pin cover, so that the plurality of ejector pins pass through the plurality of first apertures and press against the object to be separated.

13. The separation device of claim 1, wherein a contact area between the bumps and the object to be separated is smaller than a contact area between the ejector pins and the object to be separated.

14. The separation device of claim 1, further comprising ejector blocks disposed on the ejector pin plate.

15. The separation device of claim 14, wherein the idle region of the pin cover is provided with openings connected to the accommodating space, and the ejector blocks correspond to positions of the openings.

16. The separation device of claim 14, wherein the ejector blocks are further provided with the plurality of bumps.
